(19) United States
(12) Patent Application Publication
(10) Pub. No.: US 2019/0296126 A1
(43) Pub. Date: Sep. 26, 2019

(54) SYSTEMS AND METHODS FOR DUMMY GATE TIE-OFFS IN A SELF-ALIGNED GATE CONTACT (SAGC) CELL

(71) Applicant: QUALCOMM Incorporated, San Diego, CA (US)

(72) Inventors: Stanley Seungchul Song, San Diego, CA (US); Kern Rim, San Diego, CA (US); Da Yang, San Diego, CA (US); John Jianhong Zhu, San Diego, CA (US)

(21) Appl. No.: 15/927,343

(22) Filed: Mar. 21, 2018

(51) Int. Cl. H01L 29/66; H01L 29/06; H01L 23/535; H01L 27/088; H01L 27/02; H01L 21/768; H01L 29/417

(52) U.S. Cl. CPC H01L 29/66545; H01L 29/0649; H01L 23/535; H01L 27/088; H01L 21/76802; H01L 21/76877; H01L 21/76897; H01L 29/41775; H01L 27/0207

(57) ABSTRACT

Systems and methods for dummy gate tie-offs in a self-aligned gate contact (SAGC) cell are disclosed. In particular, exemplary aspects contemplate a two-part etching process to remove hardmasks formed from different materials from adjacent elements. A metal fill material may then be used to tie off the adjacent elements. The use of the two-part etching process allows SAGC techniques to be used for a first portion of a cell while still providing a technique to allow a tie-off in a second portion of the cell. The tie-off may be used with a dummy gate to provide isolation between cells.

### BACKGROUND

### I. Field of the Disclosure

The technology of the disclosure relates generally to Field-Effect Transistors (FETs) and, more particularly, to the layout of gate structures in FETs.

### II. Background

Transistors are employed in integrated circuits (ICs) in many modern electronic devices. For example, components of modern electronic devices, such as central processing units (CPUs) and memory units, employ a large quantity of transistors for logic circuits and data storage.

As electronic devices become more complex in functionality so does the need to include a greater number of transistors in such devices. Concurrently, there is pressure to provide the transistors in increasingly small sizes particularly for portable devices such as smart phones. The increase in the number of transistors is achieved in part through continued efforts to miniaturize transistors in ICs. For example, node sizes in ICs are being scaled down by a reduction in minimum metal line width in the ICs (e.g., 65 nanometers (nm), 45 nm, 28 nm, 20 nm, etc.). As a result, gate lengths within the transistors are also scalably reduced, thereby reducing channel length of the transistors and interconnects. Reduced channel length in planar transistors has the benefit of increasing drive strength (e.g., increased drive current) and providing smaller parasitic capacitances, which results in reduced circuit delay. However, as channel length in planar transistors is reduced to the point that the channel length is of the same order of magnitude as depletion layer widths, short channel effects (SCEs) can occur that offset or otherwise degrade performance More specifically, SCEs in planar transistors cause increased current leakage, reduced threshold voltage, and/or threshold voltage roll-off (i.e., reduced threshold voltage at shorter gate lengths), and therefore, reduced gate control.

To overcome the SCEs due to the reduction in gate and channel lengths in planar transistors, “wrap around” or “gate around” transistors have been developed. One common wrap or gate around transistor is a fin-based Field-Effect Transistor (FET) (finFET), which is typically assembled into cells that are incorporated into larger ICs. The density with which finFETs are packed into such cells and the close proximity of other cells poses its own manufacturing challenges. In particular, there is a need to prevent inadvertent shorting between adjacent elements. One common source of inadvertent shorting is through misalignment of contacts during the manufacturing process. One process that may be used to avoid such inadvertent shorting is through a self-aligned gate contact (SAGC) process. While effective at avoiding inadvertent shorting for transistors within a cell, there may be instances where the SAGC process hinders the ability of designers to make desired connections. Accordingly, there remains a need for a way to make more flexible interconnections using a SAGC process.

### SUMMARY OF THE DISCLOSURE

Aspects disclosed in the detailed description include systems and methods for dummy gate tie-offs in a self-aligned gate contact (SAGC) cell. In particular, exemplary aspects contemplate a two-part etching process to remove hardmasks formed from different materials from adjacent elements. A metal fill material may then be used to tie off the adjacent elements. The use of the two-part etching process allows SAGC techniques to be used for a first portion of a cell while still providing a technique to allow a tie-off in a second portion of the cell. The tie-off may be used with a dummy gate to provide isolation between cells.

In this regard in one aspect, a semiconductor device is disclosed. The semiconductor device includes a dummy gate. The semiconductor device also includes a source/drain region adjacent to the dummy gate. The semiconductor device also includes a source/drain hardmask coupled to a source/drain contact. The source/drain hardmask includes a first material. The semiconductor device also includes an opening disposed above the dummy gate down to at least a portion of a top surface of the dummy gate and disposed through a portion of the source/drain hardmask down to a portion of a top surface of the source/drain contact. The semiconductor device also includes a metal fill material disposed in the opening in conductive contact to at least the portion of the top surface of the dummy gate and in conductive contact to the portion of the top surface of the source/drain contact to tie off the dummy gate to the source/drain contact.

In another aspect, a semiconductor device is disclosed. The semiconductor device includes a dummy gate. The semiconductor device also includes a source/drain region adjacent to the dummy gate. The semiconductor device also includes a source/drain hardmask coupled to a source/drain contact. The source/drain hardmask includes a first material. The semiconductor device also includes an opening disposed above the dummy gate down to at least a portion of a top surface of the dummy gate and disposed through a portion of the source/drain hardmask down to a portion of a top surface of the source/drain contact. The semiconductor device also includes a means for filling the opening disposed in the opening in conductive contact to at least the portion of the top surface of the dummy gate and in conductive contact to the portion of the top surface of the source/drain contact to tie off the dummy gate to the source/drain contact.

In another aspect, a method for manufacturing a semiconductor device is disclosed. The method includes forming a first aperture down through a dielectric material and a first hardmask material over a gate region in the semiconductor device using a first etchant. The method also includes forming a second aperture down through the dielectric material and a second hardmask material over a source/drain region using a second etchant. The method also includes conductively coupling the gate region to the source/drain region using a metal fill material in an opening formed by the first aperture and the second aperture.

### BRIEF DESCRIPTION OF THE FIGURES

FIG. 1 is a side elevational view of a semiconductor device assembled using a self-aligned gate contact (SAGC) technique;

FIG. 2 is a simplified top view of a cell in a semiconductor device illustrating a plurality of interior active gates and dummy gates on the edges of the cell;

FIG. 3 is a simplified top view of a row of cells in a semiconductor device illustrating that dummy gates between the cells may be tied off to prevent floating;

FIG. 4 is a flowchart illustrating an exemplary process for manufacturing a dummy gate tie-off in a SAGC cell;

FIGS. 5A-5E illustrate a dummy gate at various stages of the process of FIG. 4;

FIGS. 6A and 6B illustrate an alternate fill structure for the dummy gate of FIG. 5E; and

FIG. 7 is a block diagram of an exemplary processor-based system that can include an integrated circuit (IC) having an SAGC cell with a tied-off dummy gate manufactured according to the process of FIG. 4.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include systems and methods for dummy gate tie-offs in a self-aligned gate contact (SAGC) cell. In particular, exemplary aspects contemplate a two-part etching process to remove hardmasks formed from different materials from adjacent elements. A metal fill material may then be used to tie off the adjacent elements. The use of the two-part etching process allows SAGC techniques to be used for a first portion of a cell while still providing a technique to allow a tie-off in a second portion of the cell. The tie-off may be used with a dummy gate to provide isolation between cells.

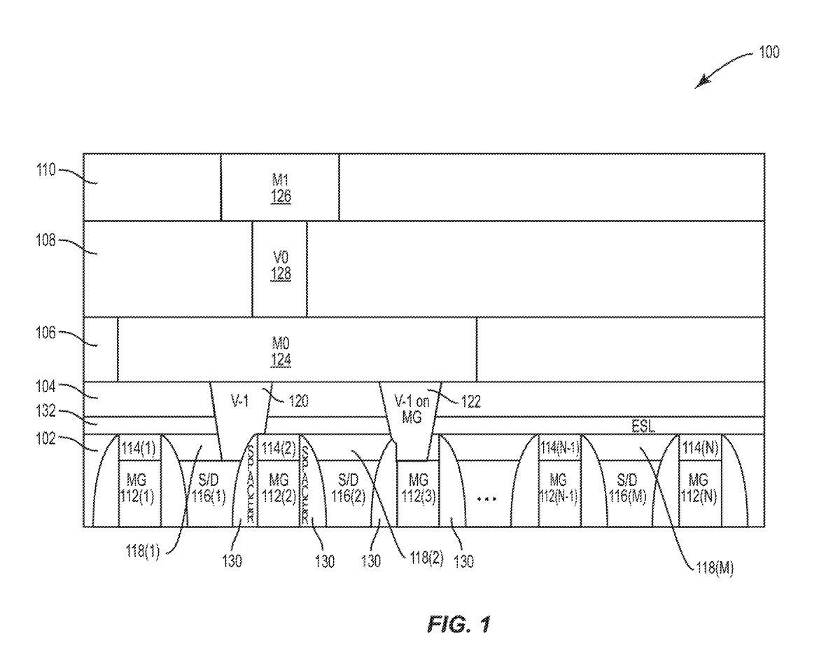

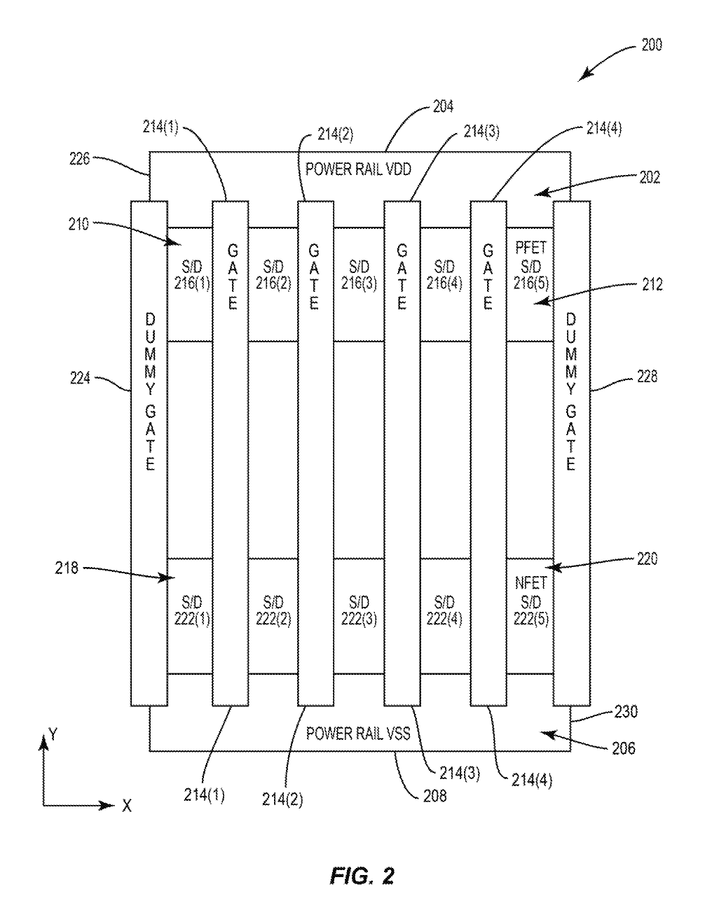

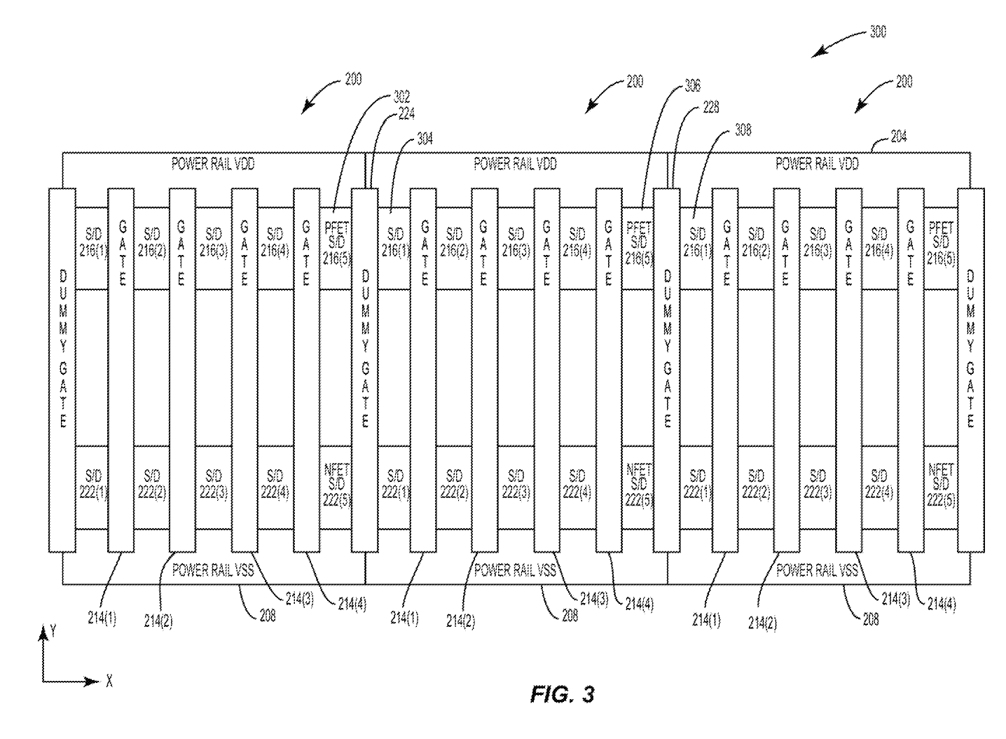

Before addressing exemplary aspects of the present disclosure, an overview of the reasoning behind using SAGC techniques is provided along with a brief discussion of a SAGC transistor with reference to FIG. 1 and an explanation of a cell and a row of cells is provided with reference to FIGS. 2 and 3 to provide context for the present disclosure.

Self-alignment, in this context, refers to structures of a semiconductor device that include one or more self-aligned contacts, such as a self-aligned gate contact, a self-aligned source/drain contact, or a combination thereof. To form a self-aligned contact, a gate hardmask structure may be formed over a gate structure and a source/drain hardmask structure may be formed over a source/drain structure. The gate hardmask structure may include a first material and the source/drain hardmask structure may include a second material. The first material and the second material may be different materials that have different etch properties (e.g., etch selectivity). For example, an etching process that is used to remove the first material from a wafer or device may leave the second material relatively intact, and vice versa. Thus, the first material may be used to “protect” device components while the second material is being etched away, and vice versa.

A first etching process may be performed to remove a portion of the gate hardmask structure to expose the gate structure. Because the first material has a different etch selectivity from the second material, the first etching process may leave the source/drain hardmask structure intact and may not expose a portion of the source/drain structure. For example, a first cavity formed by the first etching process and that is at least partially offset (e.g., misaligned) with respect to the gate structure may expose a portion of the gate structure and may not expose the source/drain structure. Accordingly, a misaligned gate via structure (e.g., a gate contact) formed in the first cavity may be isolated from the source/drain structure.

A second etching process may be performed to remove a portion of the source/drain hardmask structure, which exposes a portion of the source/drain structure. The second etching process may be a separate etching process from the first etching process. Because the second material has a different etch selectivity from the first material, the second etching process may leave any exposed gate hardmask structure intact and may not expose an additional portion(s) of the gate structure. For example, a second cavity formed by the second etching process and that is at least partially offset (e.g., misaligned) with respect to the source/drain structure may expose a portion of the source/drain structure and may not expose the gate structure. Accordingly, a misaligned source/drain via structure (e.g., a source/drain contact) formed in the second cavity may be isolated from the gate structure.

Because the first material and the second material have different etch selectivities, misalignment of a contact (e.g., a gate via structure or a source/drain via structure) may not create a short with another component of a semiconductor device. For example, a particular misaligned contact may be isolated from another contact or another component of the semiconductor device. Accordingly, the use of the gate hardmask and the source/drain hardmask may enable formation of self-aligned contacts (e.g., self-aligned via structures) without having to increase isolation spacing between contacts and other components of a semiconductor device. Thus, the SAGC techniques enable an increased tolerance of misaligned contacts and prevent (or reduce) a likelihood of a contact shorting to another component of the semiconductor device without increasing a layout area of the semiconductor device at seven nanometers (7 nm) and below.

A semiconductor device 100 formed according to a SAGC technique is illustrated in FIG. 1. The semiconductor device 100 may include a plurality of dielectric layers 102, 104, 106, 108, and 110. While five layers are shown, more layers may be included as needed or desired. The semiconductor device 100 may further include a plurality of gate structures 112(1)-112(N). The gate structures 112(1)-112(N) may be formed from a conductive metal and thus are labeled MG in FIG. 1. One or more of the gate structures 112(1)-112(N) may be positioned above a corresponding channel region (not shown) of the semiconductor device 100. Each of the gate structures 112(1)-112(N) is covered, at least in part by a corresponding first hardmask structure 114(1)-114(N). Source/drain structures 116(1)-116(M) (S/D) are positioned between adjacent gate structures 112(1)-112(N). The source/drain structures 116(1)-116(M) are covered, at least in part, by a corresponding second hardmask structure 118(1)-118(M). The first hardmask structures 114(1)-114(N) and the second hardmask structures 118(1)-118(M) have different etch selectivities. For example, the first hardmask structures 114(1)-114(N) may be oxygen-doped silicon carbide (SiC:O) and the second hardmask structures 118(1)-118(M) may be silicon nitride (SiN). Other hardmask materials may be used, but in a contemplated aspect, the etch selectivities may differ by a factor of twenty to one (i.e., an etchant will etch twenty times as much of one material than the other material). Different etching processes may selectively etch the hardmask structures to create apertures therethrough so that vias 120 and 122 (V-1) and a metal layer 124 (MO) may electrically couple a given gate structure 112(3) to a given source/drain structure 116(1). The metal layer 124 may further be coupled to an additional metal layer 126 (M1) through an upper via 128 (V0). Spacer material 130 may surround the gate structures 112(1)-112(N). An etch stop layer (ESL) 132 may be positioned above the hardmask structures

For more information about SAGC processes, the interested reader is referred to U.S. Pat. No. 9,799,560, assigned to QUALCOMM Incorporated and entitled “SELF-ALIGNED STRUCTURE,” which is hereby incorporated by reference in its entirety.

As noted above, by having different etch selectivities, it is possible to create the apertures for the vias 120 and 122 without risking inadvertent shorting between adjacent structures even at relatively small node sizes (e.g., 7 nm). The benefit of avoiding such shorts is problematic when there is a desire to make a short between adjacent structures.

One such situation where an adjacent short may be desired is when a dummy gate, such as a gate at an edge of a cell needs to be tied off to prevent the dummy gate from floating (i.e., acting as an active gate instead of a dummy gate). In such instances, it is desirable to short the dummy gate structure to one of an adjacent source or drain structure. To assist in understanding such situations, FIG. 2 illustrates a cell 200 and FIG. 3 illustrates a row 300 of a plurality of adjacent cells 200. The cell 200 of FIG. 2 has a first power rail 202 at a top edge 204 (relative to a y-axis). In an exemplary aspect, the first power rail 202 may be configured to carry a VDD voltage value. The cell 200 has a second power rail 206 at a bottom edge 208 (relative to the y-axis). In an exemplary aspect, the second power rail 206 may be configured to carry a VSS voltage value. The cell 200 includes a first active region 210, which may support P-type Field-Effect Transistors (FETs) (PFETs) 212 formed from active gates 214(1)-214(4) and source/drain structures 216(1)-216(5). The cell 200 may further include a second active region 218, which may support N-type FETs (NFETs) 220 formed from the active gates 214(1)-214(4) and source/drain structures 222(1)-222(5). The cell 200 may further include a dummy gate 224 on a left edge 226 (relative to an x-axis) and a dummy gate 228 on a right edge 230 (relative to the x-axis). The active gates 214(1)-214(4) may correspond to the gate structures 112(2)-112(N-1) of the semiconductor device 100 of FIG. 1 and may include self-aligned contacts as described above. Collectively, the NFETs 220 and the PFETs 212 may form a complementary metal oxide semiconductor (CMOS) device.

When a plurality of cells 200 are positioned in the row 300 as illustrated in FIG. 3, there are active regions 302 and 304 on either side of the dummy gate 224 and active regions 306 and 308 on either side of the dummy gate 228. If the dummy gate 224 floats (i.e., is not tied to a particular voltage), then the active regions 302 and 304 will turn the dummy gate 224 into an active gate, which is generally not what the designers intended. Likewise, if the dummy gate 228 floats, then the active regions 306 and 308 will turn the dummy gate 228 into an active gate, which again is not generally what the designers intended. Accordingly, there may be design reasons to tie off the dummy gates 224 and 228. However, the SAGC process used with the internal active gates is not conducive to tying off adjacent elements, since the whole reason the SAGC process is used is to avoid such adjacent shorts.

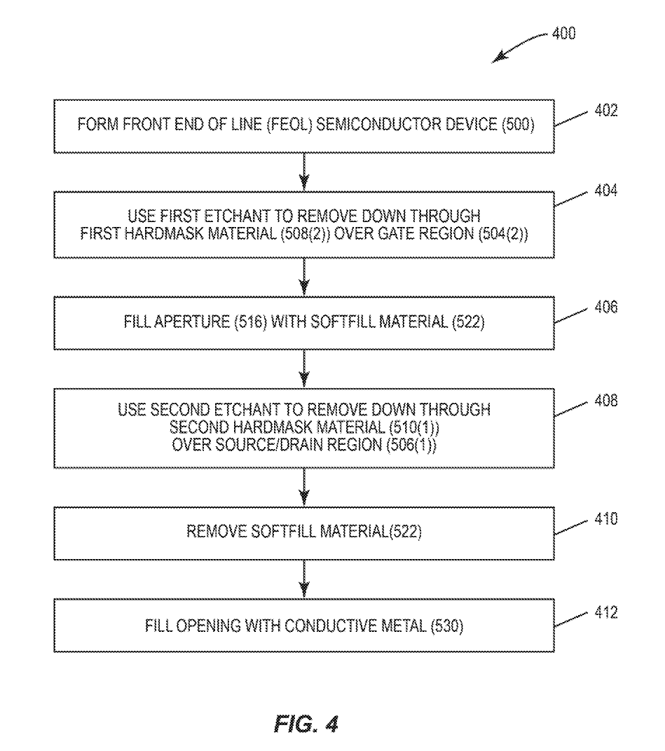

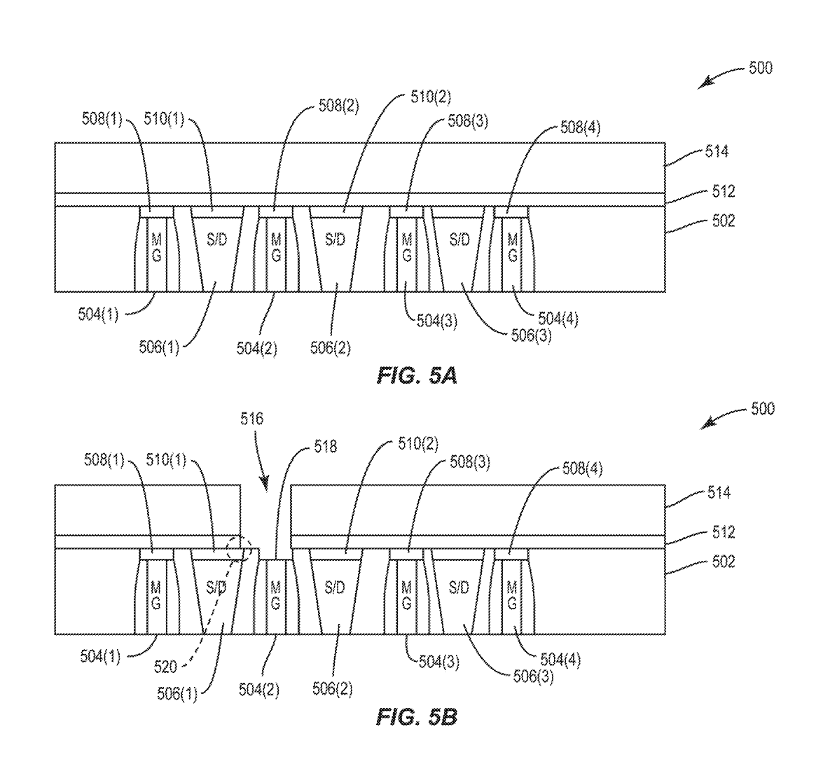

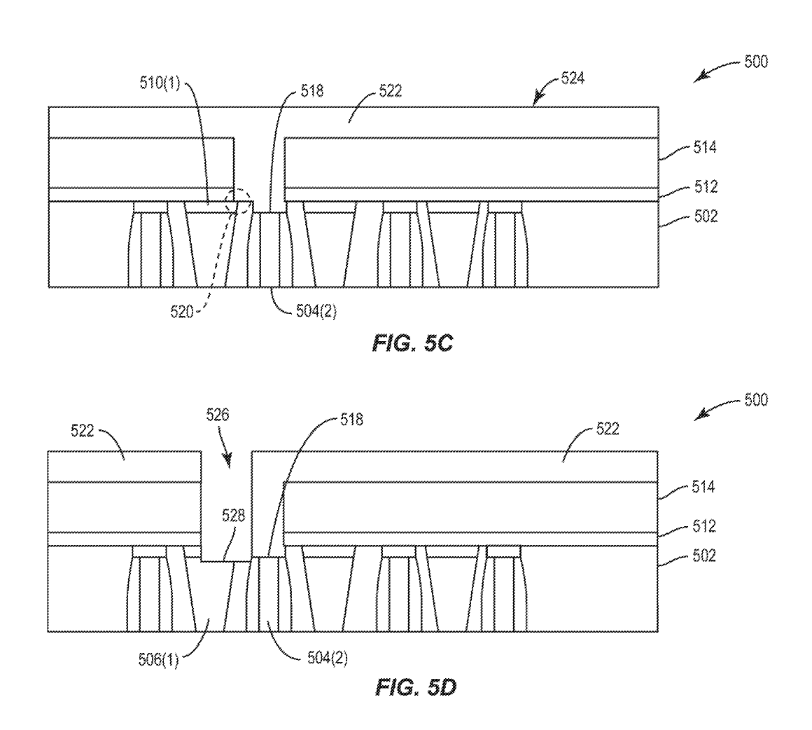

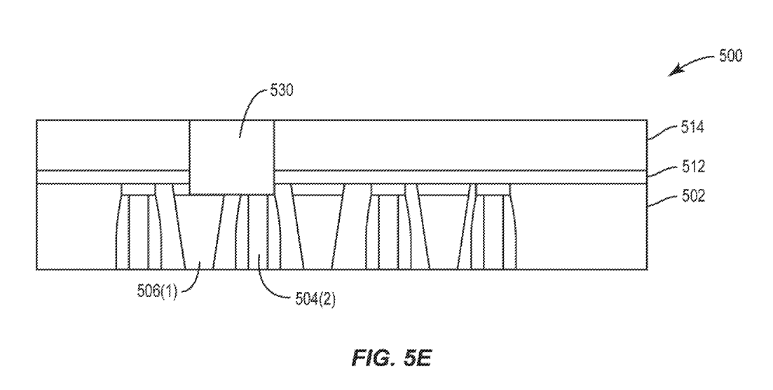

Exemplary aspects of the present disclosure provide a two-step etching process to allow tie-offs between adjacent elements even though those elements are manufactured to have the hardmasks with differing etch selectivities of a SAGC process. By providing such adjacent tie-offs, a dummy gate may remain a dummy gate instead of floating and improperly acting as an active gate. In this regard, FIG. 4 provides a flowchart for a process 400 according to an exemplary aspect of the present disclosure. FIGS. 5A-5E are used to illustrate the steps of the process 400.

The process 400 begins with formation of a front end of line (FEOL) semiconductor device 500 (block 402, see FIG. 5A). The FEOL semiconductor device 500 includes a substrate 502 that has gate regions 504(1)-504(4) therein. Source/drain regions 506(1)-506(3) are adjacent to and positioned between the gate regions 504(1)-504(4). The gate regions 504(1)-504(4) have corresponding first hardmask materials 508(1)-508(4) positioned thereon. The first hardmask materials 508(1)-508(4) have a first etch selectivity. Source/drain regions 506(1)-506(2) have corresponding second hardmask materials 510(1)-510(2) positioned thereon. The second hardmask materials 510(1)-510(2) have a second etch selectivity. An ESL 512 is positioned above the hardmask materials 508(1)-508(4) and 510(1)-510(2). A dielectric material 514 is positioned above the ESL 512.

The process 400 continues by using a first etchant to remove down through a first hardmask material 508(2) over a gate region 504(2) (block 404, see FIG. 5B). This opens up an aperture 516, which exposes a top surface 518 of the gate region 504(2) and also exposes a portion 520 of a second hardmask material 510(1). However, because the second hardmask material 510(1) has a different etch selectivity, the first etchant does not expose the source/drain region 506(1).

The process 400 continues by filling the aperture 516 and covering the dielectric material 514 with a softfill material 522 (block 406, see FIG. 5C). The softfill material 522 is used to provide a flat upper surface 524 for future processing steps. In an exemplary aspect, the softfill material may be a spin-on dielectric, such as, for example, SiCO.

The process 400 continues by using a second etchant to remove down through the second hardmask material 510(1) over the source/drain region 506(1) (block 408, see FIG. 5D). This creates an aperture 526 that exposes a top surface 528 of the source/drain region 506(1) by removing a portion of the second hardmask material 510(1). However, the softfill material 522 may still cover the top surface 518 of the gate region 504(2).

The process 400 continues by removing the softfill material 522 (block 410) and filling the resulting opening formed by the apertures 516 and 526 with a conductive metal 530 (block 412, see FIG. 5E). The conductive metal 530 forms a conductive path between the source/drain region 506(1) and the gate region 504(2), effectively tying off the gate region 504(2) to the source/drain region 506(1). That is, the conductive metal 530 acts as a metal fill material that is in conductive contact with the top portion of the gate region 504(2) and is in conductive contact with the top portion of the source/drain region 506(1). The conductive metal 530 may also be referred to as a means for filling the opening formed by the apertures 516 and 526.

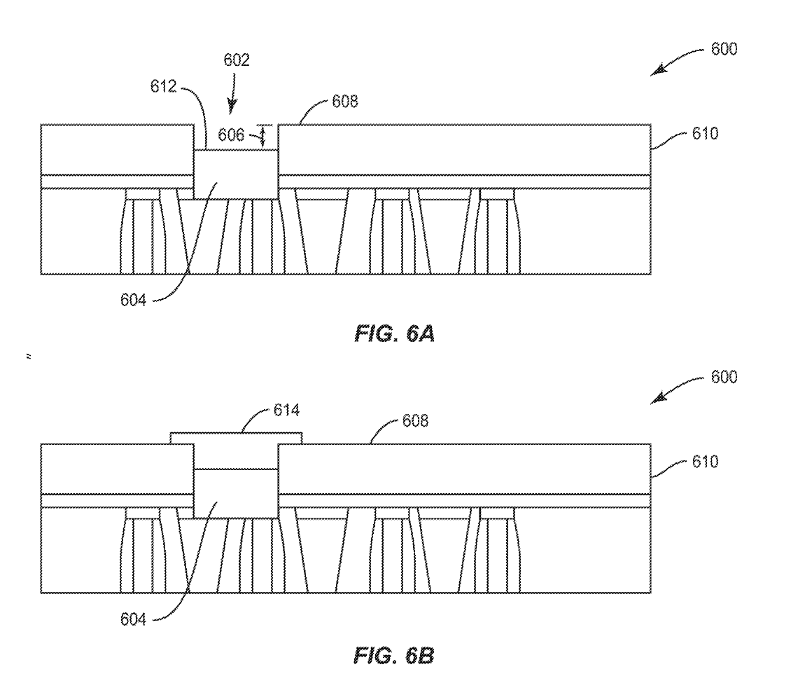

While the process 400 provides an effective tie-off for the dummy gate formed by the gate region 504(2), which prevents the dummy gate from floating, it should be appreciated that variations on the process 400 do exist. For example, it may be desirable to have the metal fill material be recessed to allow for a cap to be used. FIGS. 6A and 6B illustrate this variation. In particular, a semiconductor device 600 includes an aperture 602 in which a metal fill material 604 is positioned. The metal fill material 604 does not fill the aperture 602, but instead, there is a gap 606 between a top surface 608 of a dielectric material 610 and a top surface 612 of the metal fill material 604. A cap 614 may be positioned in the aperture 602 on top of the metal fill material 604.

The systems and methods for dummy gate tie-offs in a SAGC cell according to aspects disclosed herein may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

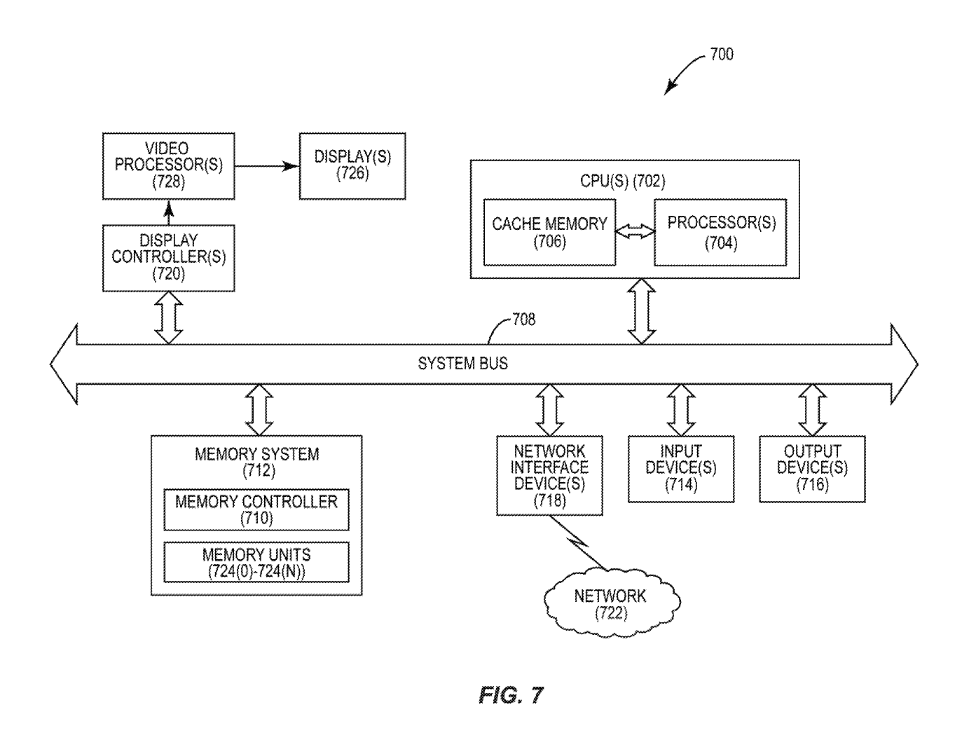

In this regard, FIG. 7 illustrates an example of a processor-based system 700 that can employ tied-off dummy gates in the semiconductor device 500 illustrated in FIG. 5E. In this example, the processor-based system 700 includes one or more central processing units (CPUs) 702, each including one or more processors 704. The CPU(s) 702 may have cache memory 706 coupled to the processor(s) 704 for rapid access to temporarily stored data. The CPU(s) 702 is coupled to a system bus 708 and can intercouple master and slave devices included in the processor-based system 700. As is well known, the CPU(s) 702 communicates with these other devices by exchanging address, control, and data information over the system bus 708. For example, the CPU(s) 702 can communicate bus transaction requests to a memory controller 710 as an example of a slave device. Although not illustrated in FIG. 7, multiple system buses 708 could be provided, wherein each system bus 708 constitutes a different fabric.

Other master and slave devices can be connected to the system bus 708. As illustrated in FIG. 7, these devices can include a memory system 712, one or more input devices 714, one or more output devices 716, one or more network interface devices 718, and one or more display controllers 720, as examples. The input device(s) 714 can include any type of input device, including, but not limited to, input keys, switches, voice processors, etc. The output device(s) 716 can include any type of output device, including, but not limited to, audio, video, other visual indicators, etc. The network interface device(s) 718 can be any devices configured to allow exchange of data to and from a network 722. The network 722 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 718 can be configured to support any type of communications protocol desired. The memory system 712 can include one or more memory units 724(0-N).

The CPU(s) 702 may also be configured to access the display controller(s) 720 over the system bus 708 to control information sent to one or more displays 726. The display controller(s) 720 sends information to the display(s) 726 to be displayed via one or more video processors 728, which process the information to be displayed into a format suitable for the display(s) 726. The display(s) 726 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. A semiconductor device, comprising:
a dummy gate;
a source/drain region adjacent to the dummy gate;
a source/drain hardmask coupled to a source/drain contact, the source/drain hardmask comprising a first material;
an opening disposed above the dummy gate down to at least a portion of a top surface of the dummy gate and disposed through a portion of the source/drain hardmask down to a portion of a top surface of the source/drain contact; and
a metal fill material disposed in the opening in conductive contact to at least the portion of the top surface of the dummy gate and in conductive contact to the portion of the top surface of the source/drain contact to tie off the dummy gate to the source/drain contact.

2. The semiconductor device of claim 1, further comprising a cap, the cap positioned in the opening on a top surface of the metal fill material.

3. The semiconductor device of claim 1, wherein the first material comprises silicon nitride.

4. The semiconductor device of claim 1, further comprising an active gate adjacent to the source/drain region.

5. The semiconductor device of claim 1 integrated into an integrated circuit (IC).

6. The semiconductor device of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

7. A semiconductor device, comprising:
a dummy gate;
a source/drain region adjacent to the dummy gate;
a source/drain hardmask coupled to a source/drain contact, the source/drain hardmask comprising a first material;
an opening disposed above the dummy gate down to at least a portion of a top surface of the dummy gate and disposed through a portion of the source/drain hardmask down to a portion of a top surface of the source/drain contact; and
a means for filling the opening disposed in the opening in conductive contact to at least the portion of the top surface of the dummy gate and in conductive contact to the portion of the top surface of the source/drain contact to tie off the dummy gate to the source/drain contact.

8-19. (canceled)
